(19) United States
(12) Patent Application Publication
(10) Pub. No.: US 2010/0193012 A1
(43) Pub. Date: Aug. 5, 2010

(54) Non-Corrosive Photovoltaic Panel Mounting Bracket

(75) Inventors: Jörgen Klammer, Mainz (DE); Benyamin Buller, Sylvania, OH (US)

Correspondence Address: STEPTOE & JOHNSON LLP, 1330 CONNECTICUT AVENUE, N.W., WASHINGTON, DC, 20036, US

(73) Assignee: First Solar, Inc., Perrysburg, OH (US)

(21) Appl. No.: 12/628,812

(22) Filed: Dec. 1, 2009

Related U.S. Application Data
(60) Provisional application No. 61/119,174, filed on Dec. 2, 2008.

(51) Int. Cl. H01L 31/048; F16M 13/00; B23P 11/00

(52) U.S. Cl. 136/251; 248/316.1; 29/428

(57) ABSTRACT

A system and method of mounting photovoltaic panels includes a mounting bracket.

### CLAIM OF PRIORITY

This application claims priority to U.S. Provisional Patent Application No. 61/119,174, filed on Dec. 2, 2008, which is incorporated by reference in its entirety.

### TECHNICAL FIELD

This invention relates to a photovoltaic module mounting bracket and a photovoltaic array including multiple photovoltaic modules.

### BACKGROUND

Photovoltaic modules receive light to generate electricity. Photovoltaic modules generally are attached to a support structure, such as a roof, the ground, or a ground pad. Multiple photovoltaic modules can be arranged in an array to increase the amount of solar energy collected. Both framed and frameless photovoltaic modules can be organized in arrays. Conventional photovoltaic module mounting brackets used to organize photovoltaic modules into arrays have metal parts which can allow electrical fields to be formed within the bracket and the photovoltaic module. The presence of electrical fields can lead to corrosion, delamination, or electrical failure of the photovoltaic module.

As a part of a photovoltaic array, a mounting bracket for mounting a photovoltaic module can provide support for the photovoltaic module while isolating the module from direct contact with the frame. The mounting bracket may be positioned at only a portion of a photovoltaic module edge, or the mounting bracket can extend the entire length, or width, or perimeter of the photovoltaic module to physically frame and protect the edges. With a non-conductive part, the mounting bracket can prevent electrical fields from forming within the bracket and the photovoltaic module. By eliminating the presence of electrical field, the photovoltaic array can be less likely to delaminate or suffer from corrosion or electrical failure than other mounting structures, thereby increasing the service lifetime of the photovoltaic module.

### SUMMARY

In one aspect, a photovoltaic module mounting bracket may include a support portion, a first flange, and a second flange. The support portion has a first end, a second end, an inner surface, and an outer surface. The first flange has a mounting region. The second flange can be opposite to the first flange. The second flange can be configured to connect to a mounting framework. The mounting region of the first flange or the whole first flange can include a non-conductive material. For example, the mounting region of the first flange or the whole first flange can be made of plastic, fiberglass extrusion, or cross-linked polyethylene.

In one aspect, a photovoltaic array can include a photovoltaic mounting framework, a photovoltaic module, and a mounting bracket. The photovoltaic module has a first surface and a second surface. The mounting bracket has a support portion, a first flange, and a second flange. The support portion has a first end, a second end, an inner surface, and an outer surface. The first flange has a mounting region contacting the first surface of photovoltaic module. The second flange can be opposite to the first flange. The second flange connects to the mounting framework.

In certain embodiments, the photovoltaic mounting framework of the photovoltaic array can include a rail formed with two or more tracks. Each track can include a member sized to accommodate a hardware connector. The mounting region of the first flange or the whole first flange can be made of a non-conductive material. For example, the mounting region or the whole first flange can be made of plastic, fiberglass extrusion, or cross-linked polyethylene.

In another aspect, a method of mounting a photovoltaic module includes inserting an edge of a photovoltaic module having a first surface into a mounting bracket. The mounting bracket includes a first flange having a mounting region contacting the first surface of the photovoltaic module. The method can include contacting the mounting region of the first flange to the first surface of the photovoltaic module. The mounting bracket can include a support portion, a first flange, and a second flange. The support portion can include a first end, a second end, an inner surface, and an outer surface. The mounting region of the first flange or the whole first flange can be made of a non-conductive material. For example, the mounting region or the whole first flange can be made of plastic, fiberglass extrusion, or cross-linked polyethylene.

The method can include fixing the framed photovoltaic module onto a track of a photovoltaic mounting framework. The photovoltaic mounting framework can include a rail formed with two or more tracks. Each track can include a member sized to accommodate a hardware connector. At least one hardware connector (e.g., a screw, nail, rivet, weld, adhesive, or braze joint) is positioned within an opening in the second flange of the mounting bracket to fix the framed photovoltaic module onto a track. At least one hardware connector (e.g., a screw, nail, rivet, weld, adhesive, or braze joint) is positioned within an opening of the mounting track of the photovoltaic array onto a surface, such as a roof, the ground, or a ground pad.

In certain embodiments, the mounting bracket can include an outward facing top extension projecting from and being perpendicular to the outer surface of the support portion of the bracket. The top extension can include a terminal portion that is directed toward the first or second flange. The mounting bracket can further include an outward facing bottom extension. The outward facing top extension and the outward facing bottom extension can define an opening sized to accommodate a support structure, such as an elongated rail.

In another aspect, a method of mounting a photovoltaic module includes inserting an edge of a photovoltaic module having a first surface into a mounting bracket. The mounting bracket includes a first flange having a mounting region contacting the first surface of the photovoltaic module. The method can include contacting the mounting region of the first flange to the first surface of the photovoltaic module. The method can include sliding the framed photovoltaic module onto a track of a photovoltaic mounting framework. The photovoltaic mounting framework can include a rail formed with two or more tracks. The tracks are elongated to the longitudinal axis of the rail. The track can be accommodated by the opening defined by the outward facing top extension and the outward facing bottom extension of the mounting bracket.

The details of one or more embodiments are set forth in the accompanying drawings and the description below. Other features, objects, and advantages will be apparent from the description and drawings, and from the claims.

### DESCRIPTION OF DRAWINGS

FIG. 1 is a partial cross-sectional view of an embodiment of a mounting support for frameless photovoltaic module.

FIG. 2 is a perspective view of an embodiment of a bracket-mounted photovoltaic module shown in FIG. 1.

FIG. 3 is a partial perspective view of an embodiment of a track of a photovoltaic mounting framework.

FIG. 4 is a partial perspective view of an embodiment of a photovoltaic array with one or more photovoltaic modules on a surface such as a roof as shown.

FIG. 5 is a partial cross-sectional view of an embodiment of a framed photovoltaic module.

FIG. 6 is a perspective view of an embodiment of a framed photovoltaic module shown in FIG. 5.

FIG. 7 is a partial perspective view of another embodiment of a photovoltaic array with one or more photovoltaic modules on a surface such as a roof as shown.

FIG. 8 is a partial cross-sectional view of another embodiment of a framed photovoltaic module.

FIG. 9 is a perspective cross-sectional view of an embodiment of mounting bracket.

FIG. 10 is a partial cross-sectional view of another embodiment of a framed photovoltaic module with a mounting track.

### DETAILED DESCRIPTION

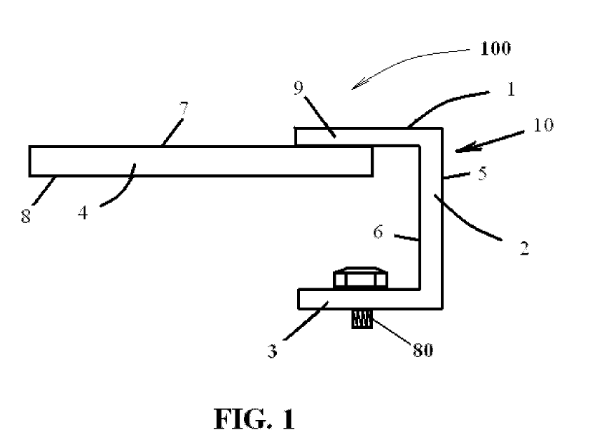

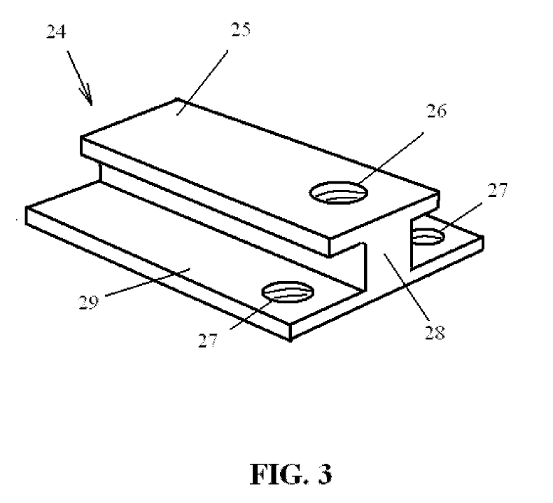

Referring to FIG. 1, a mounting bracket 10 includes a support portion 2 having an inner surface 6 and an outer surface 5. A first flange 1 is attached to one end of the support portion 2 and has a mounting region 9 attached to the first surface 7 of frameless photovoltaic module 4. Another flange 3 is attached to the other end of the support portion 2 and opposite to the first flange 1. The mounting region 9 of the first flange 1 or the whole first flange 1 can include a non-conductive material. Use of such a non-conductive material in proximity to the portion of frameless photovoltaic module 4 can diminish or eliminate an electric field being caused by mounting bracket 10 within frameless photovoltaic module 4. This in turn can reduce damage that can be caused to frameless photovoltaic module 4, for example by migrating sodium ions, such as corrosion and delamination, which can hurt device efficiency or lead to other device failure. Such non-conductive materials that can be used in mounting region 9 of first flange 1 or entire first flange 1 can be made of plastic, fiberglass extrusion, or cross-linked polyethylene. A hardware connector 80 (e.g., a screw, nail, rivet, weld, adhesive, or braze joint) may be used to mount a bracket-mounted photovoltaic module 100 to a support structure (track 24 in FIG. 3).

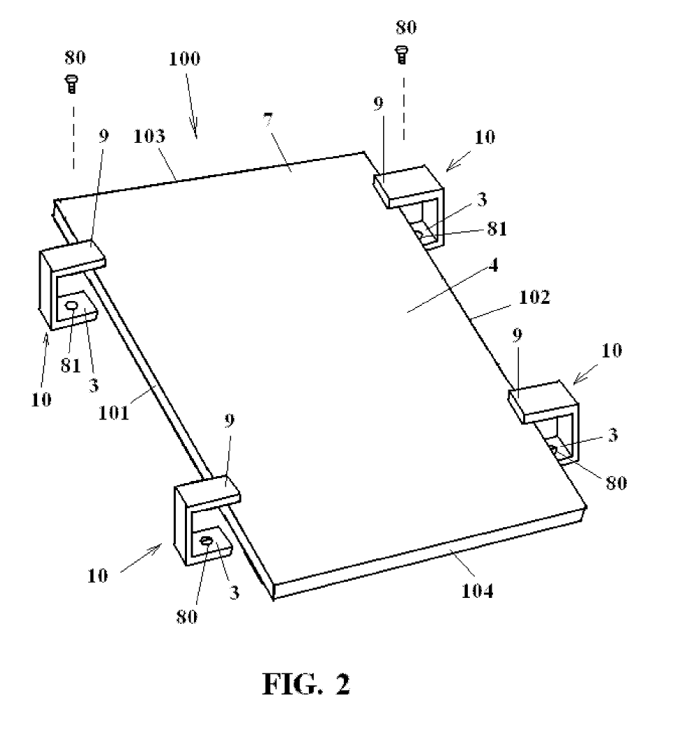

Referring to FIG. 2, a bracket-mounted photovoltaic module 100 includes a photovoltaic module 4 and a plurality of mounting brackets 10. Photovoltaic module 4 has a quadrangular shape with two parallel elongated edges 101 and 102 and two parallel transverse edges 103 and 104, each of which is generally perpendicular to elongated edges 101 and 102. As shown in FIG. 2, edges 101, 102, 103 and 104 are not framed, thus providing a frameless photovoltaic module 4 connected to one or more mounting brackets 10. Photovoltaic module 4 is attached to a plurality of mounting brackets 10. For example, mounting regions 9 may cover and attach a minimal portion of the first surface 7 of photovoltaic module 4 so as not to diminish the efficiency of the module while supporting the photovoltaic module 4.

Referring to FIG. 2, the bracket-mounted photovoltaic module 100 can be mounted directly or indirectly to a support structure. For example, as shown in FIG. 2, a bracket-mounted photovoltaic module 100 can be mounted to a support structure (track 24 in FIG. 3) directly using a hardware connector 80 (e.g., a screw, nail, rivet, weld, adhesive, or braze joint) positioned within an opening 81 in the second flange 3 of the mounting bracket 10.

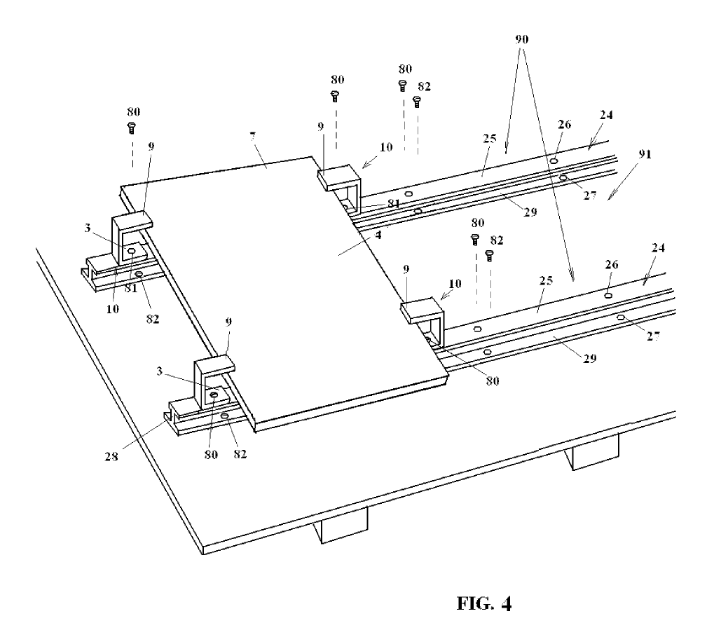

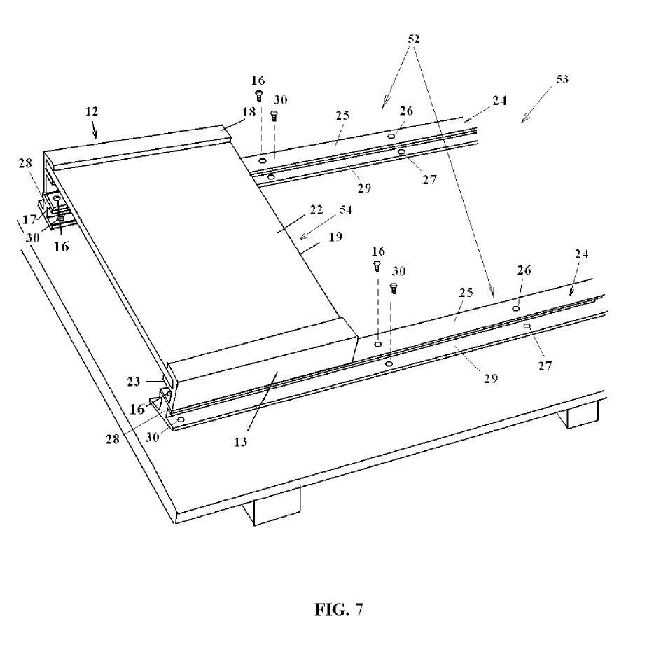

Referring to FIG. 3 as an embodiment of a part of a track 24 of a photovoltaic mounting framework (90 in FIG. 4 or 52 in FIG. 7), a track 24 may include a support portion 28. A top panel 25 is attached to the top of the support portion 28 and has at least one opening 26 to connect with the framed photovoltaic module. A bottom panel 29 is attached to the bottom of the support portion 28 and has at least one opening 27 to accommodate a hardware connector (82 in FIG. 4 or 30 in FIG. 7, e.g., a screw, nail, rivet, weld, adhesive, or braze joint) which can be used to secure the frame to, for example, a roof, the ground, a ground pad, a pipe support structure, a rack, or other type of mounting system. The track may be formed of extruded aluminum.

FIG. 4 illustrates an embodiment of a photovoltaic array 91 for removable and adjustably mounting a photovoltaic module on a surface in an operative environment. As shown by cross-reference FIG. 1-3, a photovoltaic module 4 is attached to a plurality of mounting brackets 10. At least one hardware connector 80 (e.g., a screw, nail, rivet, weld, adhesive, or braze joint) can be positioned within an opening 81 in the second flange 3 of the mounting bracket 10 to fix the photovoltaic module onto a track 24. At least one hardware connector 82 (e.g., a screw, nail, rivet, weld, adhesive, or braze joint) can be positioned within an opening 27 in the bottom panel 29 of the mounting track 24 of the photovoltaic array 91 onto a surface such as a roof as shown. A photovoltaic mounting framework 90 can include a rail formed with two or more tracks 25.

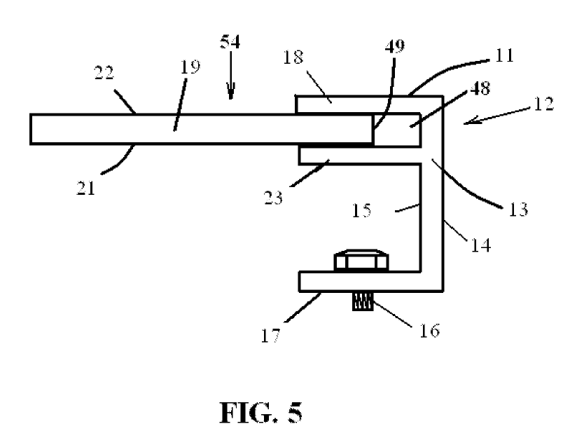

Referring to FIG. 5, a framed photovoltaic module 54 includes a mounting bracket 12 which includes a support portion 13 having an inner surface 15 and an outer surface 14. A first flange 11 is attached to one end of the support portion 13 and has a mounting region 18 contacting the first surface 22 of photovoltaic module 19. Another flange 17 is attached to the other end of the support portion 13 and opposite to the first flange 11. The bracket 12 may include an inward facing extension 23 that projects from the inner surface 15 of the support portion 13 at a position between the first flange 11 and the second flange 17. Extension 23 can be substantially parallel to the first flange 11. Extension 23 and the first flange 11 together define a groove 48 sized to accommodate an edge 49 of the photovoltaic module 19 and thereby partially frame photovoltaic module 19 to form framed photovoltaic module 54.

The mounting region 18 or the whole first flange 11 can be made of a non-conductive material. For example, the mounting region or the whole first flange can be made of plastic, fiberglass extrusion, or cross-linked polyethylene. In a possible embodiment, a hardware connector 16 (e.g., a screw, nail, rivet, weld, adhesive, or braze joint) may be used to mount a framed module 54 to a support structure (track 24 in FIG. 3). Inward facing extension 23 can be wholly or partially formed from a non-conductive material. Entire inward facing extension 23 can be non-conductive. Inward facing extension 23 can include a mounting region which is proximate to a portion of photovoltaic module 19 when mounted. Even though a portion of framed photovoltaic module 54 is physically framed and thus protected to some degree from physical damage, an electric field caused by mounting bracket 12 can still damage the device. As with the frameless photovoltaic module described in connection with FIGS. 1-4, using a non-conductive material in mounting bracket 12 in framed photovoltaic module 54 can reduce or eliminate an electric field which can be caused by a conductive mounting bracket, and thereby lessen the chance of device corrosion and failure.

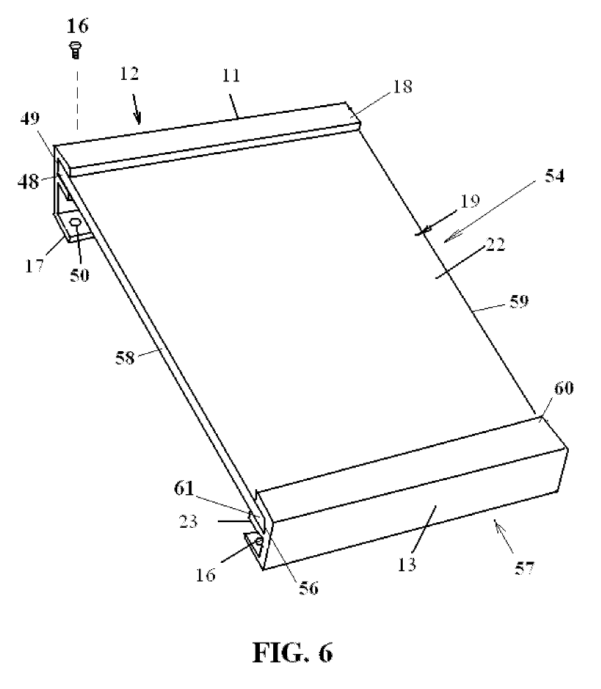

Referring to FIG. 6, a framed photovoltaic module 54 includes a photovoltaic module 19 and two mounting brackets 12 and 57. Photovoltaic module 19 has a quadrangular shape with two parallel elongated edges 58 and 59 and two parallel transverse edges 49 and 56, each of which is generally perpendicular to elongated edges 58 and 59. Photovoltaic module 19 is attached to mounting brackets 12 and 57. For example, transverse edges 49 and 56 may be inserted into grooves 48 and 61 of mounting bracket 12 and 57 respectively. Mounting region 18 and mounting region 60 may cover a minimal portion of the first surface 22 of photovoltaic module 19 so as not to diminish the efficiency of the module while protecting the panel edge.

Referring to FIG. 6, the framed photovoltaic module 54 can be mounted directly or indirectly to a support structure. For example, as shown in FIG. 6, a framed module 54 can be mounted to a support structure (track 24 in FIG. 3) directly using a hardware connector 16 (e.g., a screw, nail, rivet, weld, adhesive, or braze joint) positioned within an opening 50 in the second flange 17 of the mounting bracket 12.

FIG. 7 illustrates an embodiment of a photovoltaic array 53 for removable and adjustably mounting a photovoltaic module on a surface in an operative environment. As shown by cross-reference FIGS. 3, 5, and 6, a photovoltaic module 19 is inserted into a mounting bracket 12. At least one hardware connector 16 (e.g., a screw, nail, rivet, weld, adhesive, or braze joint) can be positioned within an opening 50 in the second flange 17 of the mounting bracket 12 to fix the framed photovoltaic module onto a track 24. At least one hardware connector 30 (e.g., a screw, nail, rivet, weld, adhesive, or braze joint) can be positioned within an opening 27 in the bottom panel 29 of the mounting track 24 of the photovoltaic array 53 onto a surface such as a roof as shown. A photovoltaic mounting framework 52 can include a rail formed with two or more tracks 25.

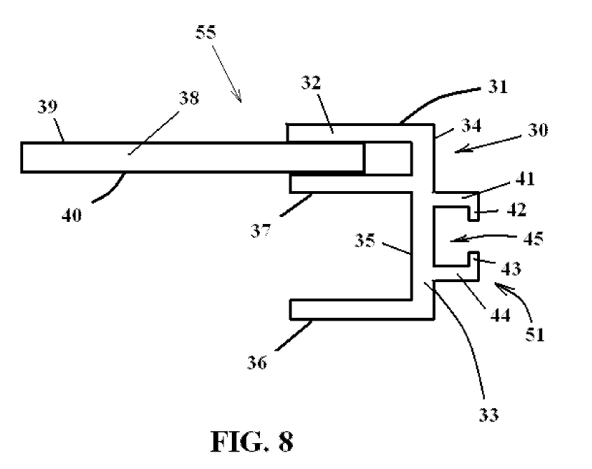

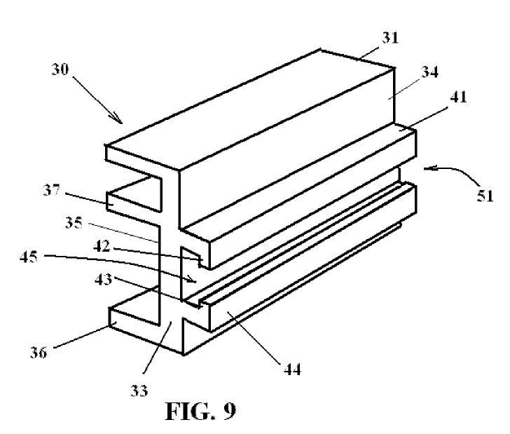

Alternatively, or in addition, as another embodiment of the present invention, mounting bracket 30 may include an outward facing attachment member 51 as shown in FIG. 8 for securing the bracket 30 directly or indirectly to a support structure (e.g., a track 30 in FIG. 9).

Referring to FIG. 8 and FIG. 9, the attachment member 51 includes an outward facing L-shaped first extension 41 projecting from and being perpendicular to the outer surface 34 of the supporting portion 33 of the mounting bracket. The terminal end 42 of the first extension 41 is directed toward the second flange 36. Bracket 30 includes an outward facing L-shaped second extension 44 that is perpendicular to the support portion 33. The terminal end 43 of second extension 44 can be directed toward the top flange 31. Outward facing first extension 41 and outward facing second extension 44 may define a C-shaped groove 45 that is sized to accommodate a support structure, such an elongated rail, which can be used to secure the frame to, for example, a roof, the ground, a ground pad, a pipe support structure, a rack, or other type of mounting system. The mounting region 32 or the whole first flange 31 can be made of a non-conductive material (e.g., plastic, fiberglass extrusion, or cross-linked polyethylene).

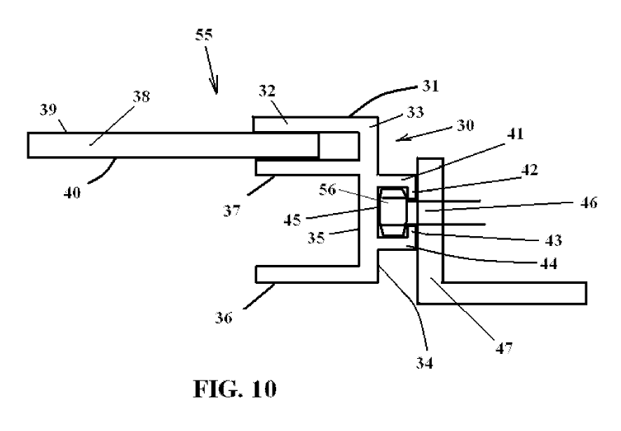

FIG. 10 illustrates an embodiment of fixing the framed photovoltaic module directly to a support structure 47. Referring to FIG. 10, terminal portion 43 of the second extension 44 extends away from support portion 33 and does not extend toward terminal portion 42 of the first extension 41. The structure opens groove 45 to facilitate inserting connector 46 into the groove 45. The head 56 of connector 46 can be angled relative to support portion 33 to seat the head 56 in groove 45 anywhere along the length of the groove.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention. Certain features of the illustrated embodiments may be enlarged or distorted relatively to others to facilitate visualization and clear understanding. In particular, small features may be enlarged for clarity of illustration, as for example the mounting bracket comparing to the photovoltaic module.

What is claimed is:

1. A photovoltaic module mounting bracket comprising:
a support portion comprising a first end, a second end, an inner surface, and an outer surface;
a first flange comprising a mounting region wherein the first flange comprises a non-conductive material; and
a second flange opposite to the first flange wherein the second flange is configured to connect to a photovoltaic array mounting framework.

2. The photovoltaic module mounting bracket of claim 1, wherein the mounting region of the first flange comprises a non-conductive material.

3. The photovoltaic module mounting bracket of claim 1, wherein the first flange comprises plastic.

4. The photovoltaic module mounting bracket of claim 2, wherein the mounting region of the first flange comprises plastic.

5. The photovoltaic module mounting bracket of claim 1, wherein the first flange comprises fiberglass extrusion.

6. The photovoltaic module mounting bracket of claim 2, wherein the mounting region of the first flange comprises fiberglass extrusion.

7. The photovoltaic module mounting bracket of claim 1, wherein the first flange comprises cross-linked polyethylene.

8. The photovoltaic module mounting bracket of claim 2, wherein the mounting region of the first flange comprises cross-linked polyethylene.

9. The photovoltaic module mounting bracket of claim 1, wherein the second flange comprises an opening configured to join the mounting bracket to a photovoltaic mounting framework using a hardware connector.

10. A photovoltaic array comprising:
a photovoltaic mounting framework;
a photovoltaic module having a first surface and a second surface;
a mounting bracket comprising:
a support portion comprising a first end, a second end, an inner surface, and an outer surface;
a first flange comprising a mounting region contacting the first surface of photovoltaic module; and
a second flange opposite to the first flange wherein the second flange connects to the mounting framework.

11. The photovoltaic array of claim 10, wherein the photovoltaic mounting framework comprises a rail formed with two or more tracks, wherein each track comprises a member sized to accommodate a hardware connector.

12. The photovoltaic array of claim 10, wherein the first flange comprises a non-conductive material.

13. The photovoltaic array of claim 10, wherein the mounting region of the first flange comprises a non-conductive material.

14. A method of installing a photovoltaic module comprising the steps of:
mounting an edge of a photovoltaic module having a first surface to a mounting bracket wherein the mounting bracket comprises:
a support portion comprising a first end, a second end, an inner surface, and an outer surface;
a first flange comprising a mounting region contacting the first surface of photovoltaic module; and
a second flange opposite to the first flange; and
contacting the mounting region of the first flange to the first surface of the photovoltaic module.

15. The method of claim 14 further comprising fixing the framed photovoltaic module onto a track of a photovoltaic mounting framework, wherein the photovoltaic mounting framework comprises:
a rail formed with two or more tracks wherein each track comprises a member sized to accommodate a hardware connector, wherein the hardware connector is used to connect the second flange of the mounting bracket and the track of the mounting framework.

16. The method of claim 14, wherein the first flange comprises a non-conductive material.

17. The method of claim 14, wherein the mounting region of the first flange comprises a non-conductive material.

18. A photovoltaic array comprising:
a photovoltaic mounting framework;
a photovoltaic module having a first surface and a second surface;
a mounting bracket comprising:
a support portion comprising a first end, a second end, an inner surface, and an outer surface;
a first flange comprising a mounting region contacting the first surface of photovoltaic module;
a second flange opposite to the first flange;
an outward facing top extension projecting from and being perpendicular to the outer surface of the supporting portion of the mounting bracket; and
an outward facing bottom extension, wherein the outward facing top extension and the outward facing bottom extension define an opening sized to accommodate a support structure.

19. The photovoltaic array of claim 18, wherein the photovoltaic mounting framework comprises a rail formed with two or more tracks, wherein the tracks are elongated to the longitudinal axis of the rail;

20. The photovoltaic array of claim 18, wherein the first flange comprises a non-conductive material.

21. The photovoltaic array of claim 18, wherein the mounting region of the first flange comprises a non-conductive material.

22. A method of installing a photovoltaic module comprising the steps of:
inserting an edge of a photovoltaic module having a first surface into a mounting bracket wherein said mounting bracket comprises:
a support portion comprising a first end, a second end, an inner surface, and an outer surface;
a first flange comprising a mounting region contacting the first surface of photovoltaic module;
a second flange opposite to the first flange;
an outward facing top extension projecting from and being perpendicular to the outer surface of the supporting portion of the mounting bracket; and
an outward facing bottom extension, wherein the outward facing top extension and the outward facing bottom extension define an opening sized to accommodate a support structure.
contacting the mounting region of the first flange to the portion of the first surface of the photovoltaic module.

23. The method of claim 22 further comprising sliding the framed photovoltaic module onto a track of a photovoltaic mounting framework, wherein the photovoltaic mounting framework comprises:
a rail formed with two or more tracks wherein the tracks are elongated to the longitudinal axis of the rail, wherein the track is accommodated by the opening defined by the outward facing top extension and the outward facing bottom extension of the mounting bracket.

24. The method of claim 22, wherein the first flange comprises a non-conductive material.

25. The method of claim 22, wherein the mounting region of the first flange comprises a non-conductive material.
